(19) United States
(12) Patent Application Publication
(10) Pub. No.: US 2026/0324354 A1
(43) Pub. Date: Oct. 15, 2026

(54) SUCTION DEVICE AND METHOD FOR MANUFACTURING SUCTION DEVICE

(71) Applicant: Sodick Co., Ltd., Kanagawa (JP)

(72) Inventors: Toshiyuki UEDA, Kanagawa (JP); Yutaka MATSUMOTO, Kanagawa (JP)

(73) Assignee: Sodick Co., Ltd., Kanagawa (JP)

(21) Appl. No.: 19/562,834

(22) Filed: Mar. 11, 2026

(30) Foreign Application Priority Data
Apr. 9, 2025 (JP) 2025-064229

(51) Int. Cl. H10P 72/72; H10P 72/78; H02N 13/00

(52) U.S. Cl. CPC H10P 72/722; H10P 72/78; H02N 13/00

(57) ABSTRACT

A suction device 1 is provided, including: a suction unit 3, having a chuck configured to be capable of suctioning a workpiece W; a base 2, including: a suction surface 21, on which the suction unit 3 is provided; and a non-suction surface 23 which is a surface on a side opposite to the suction surface 21; a temperature control pipe 4, arranged on the non-suction surface 23 and configured for a temperature control medium to flow therethrough; and a heat diffusion layer 5, covering the temperature control pipe 4 and having a thermal conductivity of 60 W/m·K or more and an apparent density of 10 g/cm³ or less.

### CROSS-REFERENCE TO RELATED APPLICATION

This application claims the priority benefit of Japanese application serial No. 2025-064229, filed on Apr. 9, 2025. The entirety of the above-mentioned patent application is hereby incorporated by reference herein and made a part of this specification.

### BACKGROUND

### Technical Field

The invention relates to a suction device and a method for manufacturing the same.

### Description of Related Art

A suction device such as an electrostatic chuck or a vacuum chuck includes a base and a suction unit provided on the base. Hereinafter, the side of the base on which the suction unit is provided is referred to as a suction surface, and the surface on the opposite side of the suction surface is referred to as a non-suction surface. The suction device may be configured to be able to control temperature to control the temperature of a workpiece as a suction target. For example, in a vapor deposition apparatus used for manufacturing an organic EL display, since the temperature variation of a substrate gripped by the suction device affects its quality, more uniform temperature control is required. Various configurations are known as temperature control modules.

As a mechanism for temperature control, it is conceivable to directly form a water channel configured to allow a temperature control medium to flow inside the base. However, a base incorporating such a water channel is difficult to manufacture. In particular, in the case where the base is made of ceramics, it is necessary to join a pair of plate-shaped ceramics, at least one of which has a groove serving as a water channel formed therein, by pressure sintering, which results in high material and processing costs, and since a sintering furnace corresponding to the size is required, the manufacturing difficulty is particularly high. Alternatively, it is conceivable to install a temperature control block incorporating a water channel so as to contact the non-suction surface of the base. In this case, since the plate thickness becomes large, the apparatus becomes large in size. In addition, if the contact between the base and the temperature control block is poor, temperature variation may also occur.

In order to easily manufacture a temperature-controllable suction device at low cost and to configure it in a compact size, it is conceivable to arrange a temperature control pipe configured to allow a temperature control medium to flow on the non-suction surface of the base. Patent Document 1 discloses an electrostatic chuck in which at least a portion of the temperature control pipe is embedded in the non-suction surface of the base.

### Prior Art Documents

### Patent Documents

Prior Art Document 1 Japanese Laid-open No. 2024-178768

If a temperature control pipe is merely arranged on the non-suction surface of the base, it is difficult to uniformly transfer the temperature to the entire workpiece, and temperature variation may occur.

The invention provides a suction device configured to be temperature-controllable, in which the occurrence of temperature variation is suppressed, and a method for manufacturing the same.

### SUMMARY

According to the invention, a suction device is provided. The suction device includes: a suction unit, having a chuck configured to be capable of suctioning a workpiece; a base, including: a suction surface, on which the suction unit is provided; and a non-suction surface, which is a surface on a side opposite to the suction surface; a temperature control pipe, arranged on the non-suction surface and configured for a temperature control medium to be able to flow therethrough; and a heat diffusion layer, covering the temperature control pipe, and having a thermal conductivity of 60 W/m·K or more and an apparent density of 10 g/cm3 or less.

In addition, according to the invention, a method for manufacturing a suction device is provided. The method includes: preparing a base that includes: a suction surface, on which a suction unit is provided, the suction unit having a chuck configured to be capable of suctioning a workpiece; and a non-suction surface, which is a surface on a side opposite to the suction surface; arranging a temperature control pipe configured for a temperature control medium to be able to flow therethrough on the non-suction surface; and forming a heat diffusion layer covering the temperature control pipe, the heat diffusion layer having a thermal conductivity of 60 W/m·K or more and an apparent density of 10 g/cm³ or less.

### BRIEF DESCRIPTION OF THE DRAWINGS

FIG. 1 is a schematic configuration diagram of a suction device of the embodiment.

FIG. 2 is a view taken along arrows II-II in FIG. 1.

FIG. 3 is a view taken along arrows III-III in FIG. 1.

FIG. 4 is an example of a flowchart of a method for manufacturing the suction device of the embodiment.

FIG. 5 illustrates a state after a base preparation process.

FIG. 6 illustrates a state after a groove formation process.

FIG. 7 illustrates a state after an arrangement process.

FIG. 8 illustrates a state after a heat diffusion layer formation process is shown.

### DESCRIPTION OF THE EMBODIMENTS

In the suction device according to the invention, a temperature control pipe is provided on the non-suction surface of the base as a temperature control module. Since the temperature control pipe is covered with a heat diffusion layer made of a high thermal conductivity material, the temperature is distributed substantially uniformly, and the occurrence of temperature variation is suppressed. Further, since the heat diffusion layer is configured to have a relatively low density and can absorb the displacement and distortion caused by differences in thermal expansion coefficient among the respective parts, cracking and peeling are avoided and the durability is improved. Consequently, the temperature range in which the temperature is controllable can be increased.

Hereinafter, embodiments of the invention are described with reference to the drawings. In each figure, each component is schematically shown, and the shape and scale are not necessarily as shown in the drawings. Various modification examples described below can be implemented by arbitrarily combining respective components.

The suction device 1 of the embodiment is specifically an electrostatic chuck, and is configured to be capable of suction-holding a workpiece W through electrical attraction, such as a Coulomb force, a Johnsen-Rahbek force, a gradient force, and the like. However, the suction device 1 is not limited to an electrostatic chuck, and may be, for example, a vacuum chuck.

The suction device 1 of the embodiment is particularly suitable for use under a vacuum environment, and can be suitably utilized as a gripping device for a substrate inside a vacuum chamber in, for example, a semiconductor manufacturing device. The semiconductor manufacturing device is, for example, a vapor deposition apparatus. However, the application field of the suction device 1 is not limited to this.

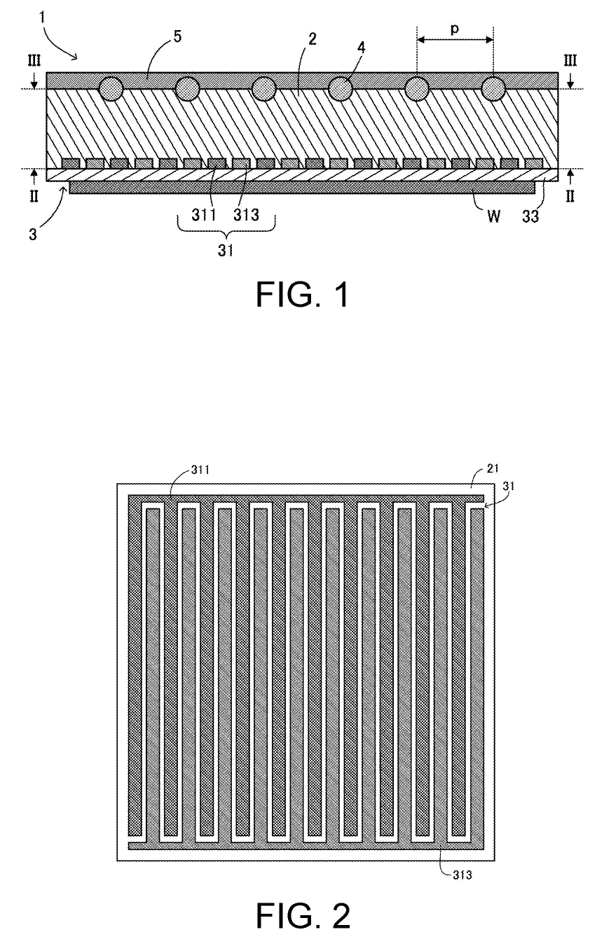

As shown in FIG. 1, the suction device 1 of the embodiment includes a base 2, a suction unit 3, a temperature control pipe 4, and a heat diffusion layer 5.

The base 2 is a plate-shaped base material on which the suction unit 3 is provided. The base 2 includes a suction surface 21 on which the suction unit 3 is provided, and a non-suction surface 23 which is a surface on a side opposite to the suction surface 21. The base 2 of the embodiment is specifically an integrally formed sintered body of ceramics and has an electrical insulation property as a whole, but may be formed of a composite material. The base 2 may be formed of, for example, alumina.

When the suction device 1 is an electrostatic chuck, the suction unit 3 includes a suction electrode 31 and a dielectric layer 33. The suction unit 3 has an arbitrary chuck configured to be capable of suctioning the workpiece W.

The suction electrode 31 is an electrode formed of a conductor and formed on the suction surface 21 of the base 2. The suction electrode 31 may be a unipolar type having only one of a positive electrode 311 and a negative electrode 313, or may be a bipolar type having both the positive electrode 311 and the negative electrode 313. The suction electrode 31 of the embodiment is a bipolar type, and as shown in FIG. 2, has a so-called comb-tooth shape in which the positive electrode 311 and the negative electrode 313 are alternately arranged at predetermined intervals. At the time of suctioning the workpiece W, predetermined voltages are respectively applied to the positive electrode 311 and the negative electrode 313. The suction electrode 31 may be formed of, for example, aluminum, copper, silver, nickel, tungsten, and alloys having these as main components.

The dielectric layer 33 is a layer formed of a dielectric body and formed to cover the suction electrode 31. The dielectric layer 33 is configured to be capable of suctioning the workpiece W, and the workpiece W is directly gripped in contact with the dielectric layer 33. When a predetermined voltage is applied to the suction electrode 31, an electrical attraction such as Coulomb force, Johnsen-Rahbek force, gradient force, and the like is generated in the dielectric layer 33, and the suctioning of the workpiece W is performed. The material of the dielectric layer 33 is selected from an arbitrary dielectric body according to the electrical resistivity as desired. The dielectric layer 33 may be formed of, for example, zircon, alumina, zirconia, titania, aluminum nitride, silica, and mixtures thereof.

As described above, the suction device 1 may be a vacuum chuck, and in this case, the suction unit 3 includes multiple pores formed on the suction surface 21, and the pores are connected to a vacuum pump.

The temperature control pipe 4 is a temperature control module configured to allow a temperature control medium to flow therethrough, and performs temperature control on the suction device 1 and consequently the workpiece W. The temperature control pipe 4 is arranged on the non-suction surface 23 of the base 2. More preferably, at least a portion of the temperature control pipe 4 is fitted into a groove 25 formed in the non-suction surface 23.

The temperature control pipe 4 is connected to a temperature controller (not shown) having at least one of a heater and a cooler, and the temperature controller heats or cools the temperature control medium. As the temperature control medium, an arbitrary fluid such as water or oil may be used. A temperature sensor that measures the temperature of a predetermined location of the suction device 1 or the workpiece W may be provided. The temperature controller may be feedback-controlled based on the temperature measured by the temperature sensor. The temperature-controllable range in the suction device 1 of the embodiment, that is, the temperature-controllable range of the temperature control medium, may be, for example, approximately 0° C or more and approximately 100° C or less.

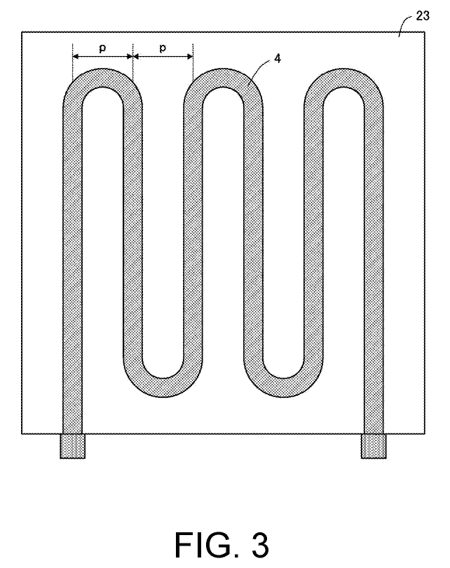

The shape of the temperature control pipe 4 is not particularly limited, but it is preferable that the temperature control pipe 4 is configured to be capable of controlling the temperature of the entire base 2 substantially uniformly. Here, in the pipes arranged parallel to each other and forming the temperature control pipe 4, the distance between the center lines of adjacent pipes is defined as an installation pitch p. As shown in FIG. 3, in the embodiment, at least portions of the temperature control piping 4 are arranged in parallel at a predetermined installation pitch p. In the suction device 1 of the invention, since the heat diffusivity is enhanced by the heat diffusion layer 5, temperature variation is unlikely to occur even if the installation pitch p is increased. By increasing the installation pitch p, the degree of freedom in design is improved, such as enabling sensors and tap holes to be arranged between portions of the temperature control piping 4. In addition, the manufacturing cost for processing the groove 25 engaged with the temperature control piping 4, which will be described later, can also be reduced. In the embodiment, the installation pitch p may be, for example, approximately 80 mm or more.

The suction device 1 of the embodiment includes the temperature control pipe 4 as a temperature control module, but other temperature control modules may be further provided. For example, a heater electrode, a sheath heater, a sheet heater, or the like may be provided as a heater. For example, a Peltier element or the like may be provided as a cooler. The temperature control pipe 4 of the embodiment is configured to be capable of both heating and cooling, but may also be configured to be capable of only one of heating and cooling.

The heat diffusion layer 5 is a layer formed of a high thermal conductivity material provided to cover the temperature control pipe 4. The heat diffusion layer 5 uniformizes the temperature distribution and suppresses the temperature variation from occurring. In addition, in the embodiment, the heat diffusion layer 5 also serves to fix the temperature control pipe 4 to the base 2. The thermal conductivity of the heat diffusion layer 5 is approximately 60 W/m·K or more, and it is particularly preferable that the thermal conductivity of the heat diffusion layer 5 is approximately 90 W/m·K or more.

The material of the heat diffusion layer 5 may be any material having good thermal conductivity, and is selected from the group consisting of, for example, aluminum (approximately 236 W/m·K), copper (approximately 403 W/m·K), nickel (approximately 94 W/m·K), silver (approximately 428 W/m·K), gold (approximately 319 W/m·K), alloys having these as main components, or combinations thereof. In particular, as the material of the heat diffusion layer 5, aluminum (including aluminum alloy) is preferable because it is excellent in thermal conductivity, workability, and availability.

The heat diffusion layer 5 is configured to have a relatively low density. The base 2, the temperature control pipe 4, and the heat diffusion layer 5 may respectively have different thermal expansion coefficients. However, with the heat diffusion layer having a low density, the displacement and distortion that come alongside the temperature control can be absorbed, cracking and peeling are prevented, and durability is improved. Consequently, the temperature range in which temperature control is possible can be increased. Since a thermal spray body has a relatively low density, a thermal spray body can be suitably adopted as the heat diffusion layer 5. The apparent density of the heat diffusion layer 5 is approximately 10 g/cm³ or less, and it is particularly preferable that it is approximately 3 g/cm³ or less. In addition, the apparent density of the heat diffusion layer 5 may be, for example, approximately 2 g/cm³ or more.

As described above, since the heat diffusion layer 5 is a thermal spray body, it also serves to fix the temperature control pipe 4 to the base 2. In the embodiment, the temperature control pipe 4 is directly fixed to the non-suction surface 23 of the base 2 by the heat diffusion layer 5. In other words, the temperature control pipe 4 is fixed to the base 2 only by the heat diffusion layer 5 without using an adhesive. The suction device 1 of the embodiment does not generate outgas caused by an adhesive, and therefore can be suitably applied to a semiconductor device where a vacuum environment and cleanliness are required. In addition, the temperature variation due to uneven application of adhesive does not occur.

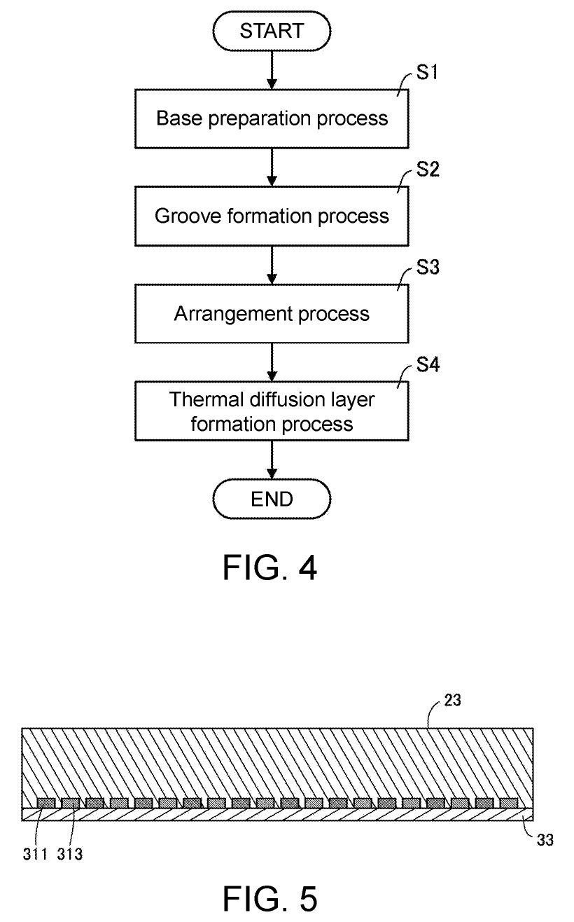

Hereinafter, a manufacturing method of the suction device 1 of the embodiment will be described with reference to FIGS. 4-8. The manufacturing method of the suction device 1 of the embodiment includes a base preparation process, a groove formation process, an arrangement process, and a heat diffusion layer formation process.

First, the base preparation process of preparing the base 2 is performed (S1). As shown in FIG. 5, in the embodiment, the base 2 on which the suction electrode 31 and the dielectric layer 33 forming the suction unit 3 are formed is prepared, but the timing of forming the suction electrode 31 and the dielectric layer 33 is not limited to this. For example, the suction electrode 31 and the dielectric layer 33 may be formed after the heat diffusion layer formation process. The suction electrode 31 and the dielectric layer 33 may be formed by any method. For example, a groove may be formed on the suction surface 21 of the base 2, a conductor may be thermally sprayed into the groove to form the suction electrode 31, and a dielectric body may be thermally sprayed to cover the suction electrode 31 to form the dielectric layer 33.

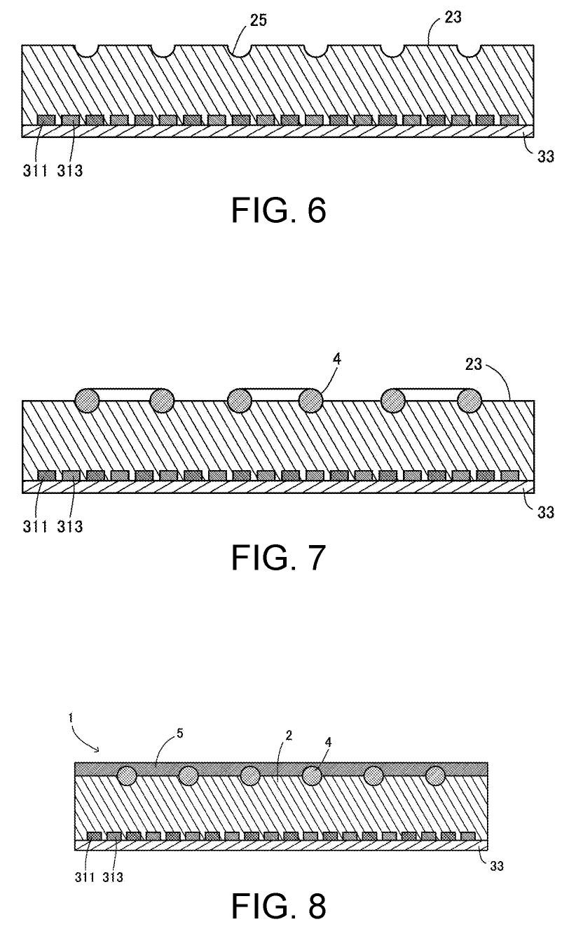

Next, the groove formation process of forming a groove in the base 2 is performed (S2). As shown in FIG. 6, the groove 25 engaged with at least a portion of the temperature control pipe 4 is formed on the non-suction surface 23 of the base 2. For the formation of the groove 25, for example, a cutting device may be used.

Next, the arrangement process of arranging the temperature control pipe 4 on the non-suction surface 23 of the base 2 is performed (S3). More specifically, as shown in FIG. 7, at least a portion of the temperature control pipe 4 is fitted into the groove 25 formed on the non-suction surface 23. By fitting the temperature control pipe 4 into the groove 25, the temperature control pipe 4 can be easily positioned and displacement is prevented. In addition, by embedding at least a portion of the temperature control pipe 4 in the base 2, the difference in height position from the heat diffusion layer 5 becomes relatively small, and adhesion is further improved.

Next, the heat diffusion layer formation process of forming the heat diffusion layer 5 is performed (S4). More specifically, a thermal spray material that is a high thermal conductivity material is thermally sprayed to cover the temperature control pipe 4, and the heat diffusion layer 5 is formed on the entire non-suction surface 23. Accordingly, the heat diffusivity is improved, and the temperature control pipe 4 is fixed to the base 2. In addition, by forming the heat diffusion layer 5 by thermal spraying, the adhesion between the base 2 and the heat diffusion layer 5 is high, and higher heat diffusivity is obtained. The heat diffusion layer 5 may have a thickness to obtain sufficient heat diffusivity and to firmly fix the temperature control pipe 4. Therefore, with the configuration of the invention, the plate thickness of the entire device can be configured to be relatively thin.

In this way, the suction device 1 shown in FIG. 8 is manufactured. By providing the heat diffusion layer 5, the temperature dispersibility is improved, and the occurrence of temperature variation is suppressed. In addition, since the heat diffusion layer 5 is configured as a low-density layer such as a thermal spray body, the durability against temperature change is high. In addition, according to the manufacturing method of the embodiment, manufacturing is relatively easy, and the suction device 1 can be configured to be compact.

The invention is not limited to the configuration of the embodiment described above, and various modifications or applications are possible without departing from the technical concept of the invention.

What is claimed is:

1. A suction device, comprising:
a suction unit, having a chuck configured to be capable of suctioning a workpiece;
a base, comprising: a suction surface, on which the suction unit is provided; and a non-suction surface, which is a surface on a side opposite to the suction surface;
a temperature control pipe, arranged on the non-suction surface and configured for a temperature control medium to be able to flow therethrough; and
a heat diffusion layer, covering the temperature control pipe, wherein the heat diffusion layer has a thermal conductivity of 60 W/m·K or more and an apparent density of 10 g/cm³ or less.

2. The suction device as claimed in claim 1, wherein the suction unit comprises:
a suction electrode, formed of a conductor formed on the suction surface; and
a dielectric layer, formed of a dielectric body covering the suction electrode.

3. The suction device as claimed in claim 1, wherein the suction unit comprises a plurality of pores formed on the suction surface and connected to a vacuum pump.

4. The suction device as claimed in claim 1, wherein the base is formed of ceramics.

5. The suction device as claimed in claim 1, wherein the temperature control pipe is fitted into a groove formed on the non-suction surface.

6. The suction device as claimed in claim 1, wherein the temperature control pipe is directly fixed to the non-suction surface by the heat diffusion layer.

7. The suction device as claimed in claim 1, wherein:
in the temperature control pipe, at least portions are arranged in parallel at a predetermined installation pitch, and
the installation pitch is 80 mm or more.

8. The suction device as claimed in claim 1, wherein the temperature control medium is configured to be temperature-controllable in a range of 0° C or more and 100° C or less.

9. The suction device as claimed in claim 1, wherein the heat diffusion layer is a thermal spray body.

10. The suction device as claimed in claim 1, wherein the heat diffusion layer is selected from a group consisting of aluminum, copper, nickel, silver, gold, alloys having these as main components, or combinations thereof.

11. The suction device as claimed in claim 1, wherein the thermal conductivity of the heat diffusion layer is 90 W/m·K or more.

12. The suction device as claimed in claim 1, wherein the apparent density of the heat diffusion layer is 3 g/cm³ or less.

13. A method for manufacturing a suction device, the method comprising:
preparing a base that comprises: a suction surface, on which a suction unit is provided, the suction unit having a chuck configured to be capable of suctioning a workpiece; and a non-suction surface, which is a surface on a side opposite to the suction surface;
arranging a temperature control pipe configured for a temperature control medium to be able to flow therethrough on the non-suction surface; and
forming a heat diffusion layer covering the temperature control pipe, the heat diffusion layer having a thermal conductivity of 60 W/m·K or more and an apparent density of 10 g/cm³ or less.

14. The method for manufacturing the suction device as claimed in claim 13, further comprising:
forming a groove engaged with the temperature control pipe on the non-suction surface,
wherein, in arranging the temperature control pipe, the temperature control pipe is fitted into the groove formed on the non-suction surface.

15. The method for manufacturing the suction device as claimed in claim 13, wherein, forming the heat diffusion layer comprises thermal-spraying a thermal spray material to cover the temperature control pipe.
